(19) United States
(12) Patent Application Publication
(10) Pub. No.: US 2025/0211286 A1
(43) Pub. Date: Jun. 26, 2025

(54) COMMUNICATION SYSTEM, ELECTRONIC DEVICE, AND NEAR-FIELD COMMUNICATION CIRCUIT IN DIFFERENTIAL MODE

(71) Applicant: Getac Technology Corporation, New Taipei City (TW)

(72) Inventor: MIN-YU WANG, Taipei City (TW)

(21) Appl. No.: 18/830,902

(22) Filed: Sep. 11, 2024

(30) Foreign Application Priority Data
Dec. 22, 2023 (CN) 202311778618.6

(51) Int. Cl. H04B 5/48; H03H 7/06; H04B 5/43

(52) U.S. Cl. CPC H04B 5/48; H03H 7/06; H04B 5/43

(57) ABSTRACT

The present invention provides a communication system, an electronic device, and a near-field communication circuit in a differential mode, including a first substrate and a second substrate. The first substrate includes a near-field communication integrated chip and a filter connected to the near-field communication integrated chip; and the second substrate includes an impedance adjustment circuit connected to the filter via a coaxial line and a near-field communication antenna circuit connected to the impedance adjustment circuit. Thus, the near-field communication integrated chip on the first substrate can be shared and works with different antenna circuits and impedance adjustment circuits.

### CROSS-REFERENCE TO RELATED APPLICATION

This application claims the priority benefit of Chinese Patent Application 202311778618.6, filed Dec. 22, 2023. The entirety of the above-mentioned patent application is hereby incorporated by reference herein and made a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE INVENTION

The present invention relates to a near-field communication circuit, and in particular to a near-field communication circuit in a differential mode, a communication system, and an electronic device.

### BACKGROUND OF THE INVENTION

An integrated chip, a filter, an impedance adjustment circuit, and an antenna of a near-field communication circuit are mostly fabricated on the same printed circuit board. A small number of near-field communication circuits have their antennas additionally fabricated on another printed circuit board, and these near-field communication circuits are only limited to near-field communication circuits in single-ended mode that can share other modules while only replace the antennas. However, the interference resistance of this type of single-ended near-field communication circuits is poor. Therefore, an important subject to be addressed in this technical field is how to fabricate a near-field communication circuit that has good interference resistance properties and can also reside in the same module.

### SUMMARY OF THE INVENTION

The present invention provides a near-field communication circuit that has good interference resistance and can share a module, a communication system, and an electronic device.

The electronic device provided by the present invention includes a near-field communication circuit in a differential mode. The near-field communication circuit in a differential mode includes a first substrate and a second substrate. The first substrate includes a near-field communication integrated chip and a filter connected to the near-field communication integrated chip; and the second substrate includes an impedance adjustment circuit connected to the filter via a coaxial line and a near-field communication antenna circuit connected to the impedance adjustment circuit.

The communication system provided by the present invention includes a near-field communication circuit in a differential mode. The near-field communication circuit in a differential mode includes a first substrate and a second substrate. The first substrate includes a near-field communication integrated chip and a filter connected to the near-field communication integrated chip; and the second substrate includes an impedance adjustment circuit connected to the filter via a coaxial line and a near-field communication antenna circuit connected to the impedance adjustment circuit.

The near-field communication circuit in a differential mode provided by the present invention includes a first substrate and a second substrate. The first substrate includes a near-field communication integrated chip and a filter connected to the near-field communication integrated chip; and the second substrate includes an impedance adjustment circuit connected to the filter via a coaxial line and a near-field communication antenna circuit connected to the impedance adjustment circuit.

In an embodiment of the present invention, the filter is an electromagnetic compatibility filter.

In an embodiment of the present invention, the impedance adjustment circuit includes an impedance adjustment portion and a damping resistor portion.

In an embodiment of the present invention, the second substrate can be replaced with a third substrate, and the third substrate includes: another impedance adjustment circuit connected to the filter via the coaxial line; and another near-field communication antenna circuit connected to the other impedance adjustment circuit.

In an embodiment of the present invention, the impedance adjustment circuit and the other impedance adjustment circuit have different impedance adjustment values.

In the present invention, the integrated chip and the filter, and the impedance adjustment circuit and the antenna are separately fabricated on different substrates, thus providing the near-field communication circuit that has good interference resistance and can share a module, a communication system, and an electronic device.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of a near-field communication circuit according to an embodiment of the present invention.

FIG. 2 is a schematic diagram of an electronic device according to an embodiment of the present invention.

FIG. 3 is a schematic diagram of a communication system according to an embodiment of the present invention.

### DETAILED DESCRIPTION OF PREFERRED EMBODIMENTS

To make the objectives, technical solutions, and advantages of the present invention more comprehensible, the following describes the present invention in detail with reference to embodiments and accompanying drawings. It should be understood that the specific embodiments described herein are merely used to explain the present invention but are not intended to limit the present invention. All other embodiments obtained by persons of ordinary skill in the technical field based on the embodiments of present invention without creative efforts shall fall within the protection scope of present invention.

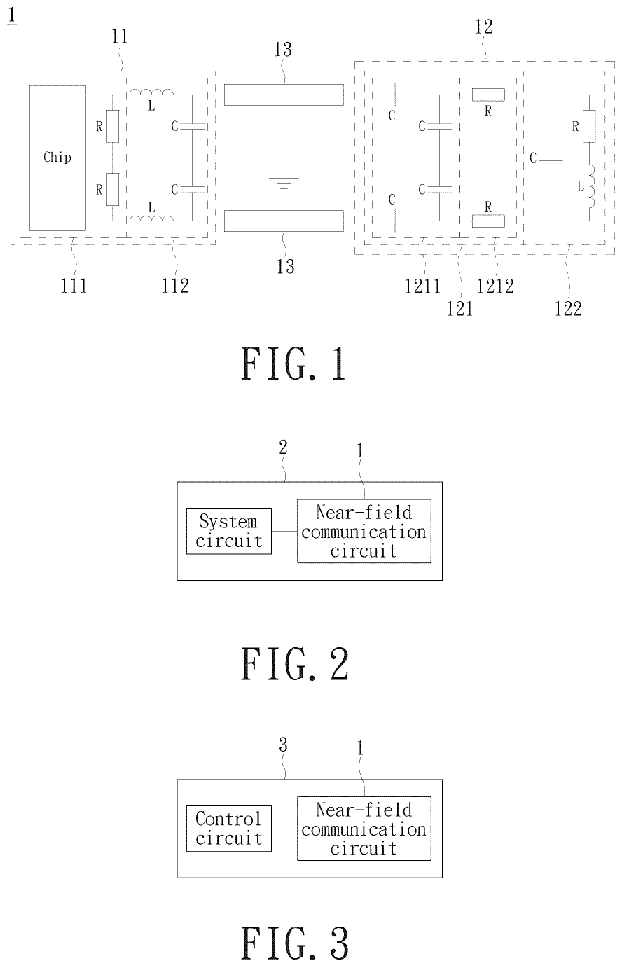

Refer to FIG. 1, which is a schematic diagram of a near-field communication circuit according to an embodiment of the present invention. A near-field communication circuit 1 provided by this embodiment is a near-field communication circuit 1 in a differential mode, where the near-field communication circuit 1 in a differential mode includes a first substrate 11 and a second substrate 12. The first substrate 11 is connected to the second substrate 12 via a coaxial line 13. It should be noted that for ease of illustration, the two coaxial lines 13 in FIG. 1 are essentially the same coaxial line 13. In addition, persons of ordinary skill in the art can design the position of a grounding point (a common ground point) based on the actual circuit design requirements.

Specifically, the first substrate 11 includes a near-field communication integrated chip 111 and a filter 112 connected to the near-field communication integrated chip 111. It should be noted that the filter 112 is an electromagnetic compatibility filter. The second substrate 12 includes a first impedance adjustment circuit 121 connected to the filter 112 via a coaxial line 13 and a first near-field communication antenna circuit 122 connected to the first impedance adjustment circuit 121. It can be noted that the first impedance adjustment circuit 121 includes an impedance adjustment (impedance adjustment) portion 1211 and a damping resistor (damping resistor) portion 1212. In addition, elements of the filter 112, the first impedance adjustment circuit 121, and the first near-field communication antenna circuit 122 in FIG. 1 and their connection relationship are illustrated, and can be replaced by the other equivalent circuits, and the present invention is not limited thereto.

As the first substrate 11 is connected to the second substrate 12 via the coaxial line 13, the second substrate 12 of the near-field communication circuit 1 can be replaced with a third substrate, such that the third substrate is connected to the first substrate 11 via the coaxial line 13. The third substrate, similar to the second substrate 12, includes a second impedance adjustment circuit connected to the filter 112 via the coaxial line 13 and a second near-field communication antenna circuit connected to the second impedance adjustment circuit. It can be noted that the second impedance adjustment circuit and the first impedance adjustment circuit have different impedance adjustment values, and therefore the second near-field communication antenna circuit is also different from the first near-field communication antenna circuit 122.

Refer to FIG. 2, which is a schematic diagram of an electronic device according to an embodiment of the present invention. An electronic device 2 provided by this embodiment includes a near-field communication circuit 1 and a system circuit. The near-field communication circuit 1 is connected to the system circuit, so as to transmit a near-field communication signal to the system circuit or receive a near-field communication signal from the system circuit. It can be noted that the electronic device 2 may be a computer apparatus that has a computational capability and capabilities of wireless receiving and transmitting signals, such as a personal computer, a tablet, or a laptop.

Refer to FIG. 3, which is a schematic diagram of a communication system according to an embodiment of the present invention. A communication system 3 provided by this embodiment includes a near-field communication circuit 1 and a control circuit. The near-field communication circuit 1 is connected to the control circuit, so as to transmit a near-field communication signal to the control circuit or receive a near-field communication signal from the control circuit. It can be noted that the communication system 3 may be a hardware apparatus that has a computational capability and capabilities of wireless receiving and transmitting signals such as a wireless communication apparatus, a device, a circuit, or hardware.

In summary, according to the communication system, the electronic device, and the near-field communication circuit in a differential mode provided by the present invention, the integrated chip and the filter, and the impedance adjustment circuit and the antenna are separately fabricated on different substrates, thus providing the near-field communication circuit that has good interference resistance and can share a module, the communication system, and the electronic device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A near-field communication circuit in a differential mode, comprising:
a first substrate comprising a near-field communication integrated chip and a filter, wherein the filter is connected to the near-field communication integrated chip; and
a second substrate comprising an impedance adjustment circuit and a near-field communication antenna circuit, wherein
the impedance adjustment circuit is connected to the filter via a coaxial line; and
the near-field communication antenna circuit is connected to the impedance adjustment circuit.

2. The near-field communication circuit in a differential mode according to claim 1, wherein the filter is an electromagnetic compatibility filter.

3. The near-field communication circuit in a differential mode according to claim 1, wherein the impedance adjustment circuit comprises an impedance adjustment portion and a damping resistor portion.

4. The near-field communication circuit in a differential mode according to claim 1, wherein the second substrate is configured to be replaced with a third substrate, and the third substrate comprises:
a second impedance adjustment circuit connected to the filter via the coaxial line; and
a second near-field communication antenna circuit connected to the second impedance adjustment circuit.

5. The near-field communication circuit in a differential mode according to claim 4, wherein the impedance adjustment circuit and the second impedance adjustment circuit have different impedance adjustment values.

6. An electronic device, comprising:
a near-field communication circuit in a differential mode, comprising a first substrate and a second substrate, wherein
the first substrate comprises a near-field communication integrated chip and a filter, and the filter is connected to the near-field communication integrated chip; and
the second substrate comprises an impedance adjustment circuit and a near-field communication antenna circuit, wherein
the impedance adjustment circuit is connected to the filter via a coaxial line; and
the near-field communication antenna circuit is connected to the impedance adjustment circuit.

7. The electronic device according to claim 6, wherein the filter is an electromagnetic compatibility filter.

8. The electronic device according to claim 6, wherein the impedance adjustment circuit comprises an impedance adjustment portion and a damping resistor portion.

9. The electronic device according to claim 6, wherein the second substrate is configured to be replaced with a third substrate, and the third substrate comprises:
a second impedance adjustment circuit connected to the filter via the coaxial line; and
a second near-field communication antenna circuit connected to the second impedance adjustment circuit.

10. The electronic device according to claim 9, wherein the impedance adjustment circuit and the second impedance adjustment circuit have different impedance adjustment values.

11. A communication system, comprising:
a near-field communication circuit in a differential mode, comprising a first substrate and a second substrate, wherein
the first substrate comprises a near-field communication integrated chip and a filter, and the filter is connected to the near-field communication integrated chip; and
the second substrate comprises an impedance adjustment circuit and a near-field communication antenna circuit, wherein
the impedance adjustment circuit is connected to the filter via a coaxial line; and
the near-field communication antenna circuit is connected to the impedance adjustment circuit.

12. The communication system according to claim 11, wherein the filter is an electromagnetic compatibility filter.

13. The communication system according to claim 11, wherein the impedance adjustment circuit comprises an impedance adjustment portion and a damping resistor portion.

14. The communication system according to claim 11, wherein the second substrate is configured to be replaced with a third substrate, and the third substrate comprises:
a second impedance adjustment circuit connected to the filter via the coaxial line; and
a second near-field communication antenna circuit connected to the second impedance adjustment circuit.

15. The communication system according to claim 14, wherein the impedance adjustment circuit and the second impedance adjustment circuit have different impedance adjustment values.
